(19) United States
(12) Patent Application Publication
(10) Pub. No.: US 2026/0275525 A1
(43) Pub. Date: Sep. 17, 2026

(54) SUSCEPTOR RINGS FOR USE IN REACTOR SYSTEMS, SUSCEPTOR RING ASSEMBLIES INCLUDING SUSCEPTOR RINGS, AND RELATED METHODS

(71) Applicant: ASM IP Holding B.V., Almere (NL)

(72) Inventors: Aniket Chitale, Phoenix, AZ (US); Fan Gao, Chandler, AZ (US); Junwei Su, Chandler, AZ (US); Wentao Wang, Chandler, AZ (US); Han Ye, Phoenix, AZ (US)

(21) Appl. No.: 19/560,274

(22) Filed: Mar. 9, 2026

Related U.S. Application Data
(60) Provisional application No. 63/770,819, filed on Mar. 12, 2025.

(51) Int. Cl. C23C 16/458

(52) U.S. Cl. CPC C23C 16/4585

(57) ABSTRACT

A susceptor ring assembly and reactor system are provided for injecting gases into a reaction chamber. The susceptor ring assembly comprises a susceptor ring with a susceptor plate, side members, and gas channels. A susceptor is seated within the susceptor aperture and supports a substrate. A first gas outlet injects a first flow of gas perpendicular to a second flow injected from an injection flange, both of which are independently controlled. A method of injecting a gas into the reaction chamber involves seating a substrate on the susceptor ring, supplying gas to an injector tube, flowing the gas through the injector tube and into an injection channel, and injecting the gas from the channel onto the substrate. The reactor system comprises the reaction chamber, susceptor ring assembly, and injector tubes, allowing for independent control of the gas flows.

### CROSS-REFERENCE TO RELATED APPLICATIONS

This application is a nonprovisional of, and claims priority to and the benefit of, U.S. Provisional Patent Application No. 63/770,819, filed Mar. 12, 2025 and entitled “SUSCEPTOR RINGS FOR USE IN REACTOR SYSTEMS, SUSCEPTOR RING ASSEMBLIES INCLUDING SUSCEPTOR RINGS, AND RELATED METHODS,” which is hereby incorporated by reference herein.

### FIELD

The present disclosure generally relates to apparatus, systems, and methods used in the formation of electronic devices. More particularly, the disclosure relates to apparatus, systems, and methods suitable for gas injection during substrate processing.

### BACKGROUND

Gas-phase reactors, such as chemical vapor deposition (CVD) reactors and the like, can be used for a variety of applications, including depositing and/or etching materials on a substrate surface, and cleaning a surface of the substrate. For example, gas-phase reactors can be used to deposit epitaxial layers on a substrate to form devices, such as semiconductor devices, flat panel display devices, photovoltaic devices, microelectromechanical systems (MEMS), and the like.

A typical gas-phase epitaxial reactor system includes a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gases and/or carrier/purge gases) to the reaction chamber, a susceptor to retain and heat a substrate, and an exhaust source fluidly coupled to the reaction chamber. Further, epitaxial reactor systems can include one or more heaters (e.g., lamps) and/or temperature measurement devices (e.g., a thermocouple).

During deposition, such as epitaxial deposition, and particularly during deposition of doped or multi-component films, it is often desirable to control film properties, such as thickness and composition of a deposition film to a far edge (e.g., the outermost approximately 5% to 15% of the radius) of a substrate. With typical methods and systems, such control can be difficult. Accordingly, improved methods and systems are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to improved apparatus, systems, and methods suitable for depositing material on a surface of a substrate and/or other processes. While the ways in which various embodiments of the present disclosure address drawbacks of prior systems and methods are discussed in more detail below, in general, various embodiments of the disclosure provide methods and systems that can be used to, for example, deposit epitaxial material in a more controlled manner. For example, exemplary apparatus, systems, and methods can be used to reduce and control roll-up and/or roll-down at the far edge of a substrate while processing the substrate. Examples of the disclosure can improve uniformity of film thickness, composition, and/or the like.

As detailed below, and in accordance with examples of the disclosure, susceptor rings comprising a susceptor plate having a first side member that includes one or more internal gas channels are disclosed. Each internal gas channel can be in fluid communication with an internal injection channel. These injection channels can extend from the internal gas channels to one or more outlets located on the inner edge of the first side member. In various embodiments, the first side member extends from the upper surface of the susceptor plate, and the internal injection channels are angled below the plane of the susceptor plate. This configuration of the susceptor ring, susceptor, and substrate, allows the gas injected via the outlets to be directed downward toward the substrate seated on a susceptor within the susceptor plate. The ability to control the flow direction as well as the flow rate of the process gas injected from the susceptor ring enables the tuning of various properties across the substrate being processed. For example, the dopant concentration near the wafer edge can be varied by the flow of one or more precursors injected near the wafer edge from the outlet in the side member of the susceptor plate. In addition, such gas injection can provide for more control or facilitate obtaining a desired flow profile for a process (e.g., deposition and/or etching) on the outer edges of the substrate where issues like roll-up and roll-down can otherwise occur. Such gas injection can further provide significant advantages in reducing non-uniformity of films deposited or etched and/or provide desired flow profiles.

In accordance with example embodiments, a susceptor ring for use in a reactor system is provided, the susceptor ring comprising a susceptor plate having an upper surface and a lower surface, a first side member extending from the upper surface, and a susceptor aperture extending from the upper surface to the lower surface and configured to receive a susceptor configured to support a substrate; a first gas channel disposed within the first side member, the first gas channel configured to couple with a first injector tube for supplying a gas to the first gas channel; and a first injection channel disposed within the first side member at a first injection angle, the first injection channel extending from the first gas channel to a first gas outlet disposed in a first inner edge of the first side member.

In some embodiments, the susceptor plate comprises a single monolithic body.

In some embodiments, the first injection angle is between 5 degrees and 35 degrees.

In some embodiments, the susceptor plate further comprises a second side member longitudinally spaced apart from the first side member and extending from the upper surface of the susceptor plate.

In some embodiments, the susceptor ring further comprising a second gas channel disposed within the susceptor plate, the second gas channel configured to couple with a second injector tube for supplying the gas to the second gas channel, and a second injection channel disposed within the susceptor plate at a second injection angle, the second injection channel extending from the second gas channel to a second gas outlet disposed in a second inner edge of the second side member.

In some embodiments, the second injection angle is between 5 degrees and 35 degrees.

In some embodiments, the first gas outlet and the second gas outlet are positioned laterally opposing each other on either side of the susceptor aperture.

In accordance with example embodiments, a reactor system is provided, the reactor system comprising: a reaction chamber comprising an injection end coupled to an injection flange and an exhaust end coupled to an exhaust flange; a susceptor ring assembly disposed within the reaction chamber, the susceptor ring assembly comprising: a monolithic susceptor ring comprising a susceptor plate having an upper surface and a lower surface, a first side member extending from the upper surface, a susceptor aperture extending from the upper surface to the lower surface, a first gas channel disposed within the first side member, and a first injection channel disposed within the first side member at a first injection angle, the first injection channel extending from the first gas channel to a first gas outlet disposed in a first inner edge; a first injector tube coupled to the first gas channel and at least partially disposed within the first gas channel; and a susceptor at least partially disposed within the susceptor aperture and configured to support a substrate. In such examples, the first gas outlet is configured to independently provide a first flow of a gas into the reaction chamber and the injection flange is configured to independently provide a second flow of the gas into the reaction chamber and the first flow is substantially perpendicular to the second flow.

In some embodiments, the reactor system further comprises a gas source system fluidly coupled to the first injector tube and the injection flange, the gas source system including a first flow controller for controlling the first flow and a second flow controller for controlling the second flow.

In some embodiments, wherein the gas source system comprises a dopant gas source and the gas supplied to the first injector tube and the injection flange is a dopant gas.

In some embodiments, the first injection angle is between 5 degrees and 35 degrees.

In some embodiments, the susceptor plate further comprises a second side member longitudinally spaced apart from the first side member and extending from the upper surface, a second gas channel disposed within the susceptor plate, and a second injection channel disposed within the susceptor plate at a second injection angle, the second injection channel extending from the second gas channel to a second gas outlet disposed in a second inner edge of the second side member.

In some embodiments, the reactor system further comprises a second injector tube coupled to the second gas channel and at least partially disposed within the second gas channel.

In some embodiments, the first gas outlet and the second gas outlet are positioned laterally opposing each other on either side of the susceptor aperture.

In accordance with example of embodiments, a method of injecting a gas into a reaction chamber is provided, the method comprising: seating a substrate on a susceptor ring assembly within a reaction chamber of a reactor system, the susceptor ring assembly comprising: a monolithic susceptor ring comprising a susceptor plate having an upper surface and a lower surface, a first side member extending from the upper surface, and a susceptor aperture extending from the upper surface to the lower surface; a first gas channel disposed within the first side member; and a first injection channel disposed within the first side member at a first injection angle, the first injection channel extending from the first gas channel to a first gas outlet disposed in a first inner edge; a first injector tube coupled to the first gas channel and at least partially disposed within the first gas channel; a rotatable susceptor at least partially disposed within the susceptor aperture; supplying the gas to the first injector tube at least partially disposed within the first gas channel; flowing the gas supplied from the first injector tube to the first injection channel; and injecting a first flow of the gas supplied from the first injection channel from the first gas outlet on to the substrate seated on the rotatable susceptor of the susceptor ring assembly; and injecting a second flow of the gas from an injection flange coupled to the reaction chamber.

In some embodiments, the first flow of the gas is substantially perpendicular to the second flow of the gas.

In some embodiments, the first flow of the gas is independently controlled by a first flow controller and the second flow of the gas is independently controlled by a second flow controller.

In some embodiments, the gas comprises a dopant gas.

In some embodiments, the first injection angle is between 5 degrees and 35 degrees, and the dopant gas is injected through the first gas outlet downward toward and across the substrate.

In some embodiments, the monolithic susceptor ring further comprises a second gas channel disposed within the susceptor plate, the second gas channel configured to couple with a second injector tube for supplying the gas to the second gas channel, and a second injection channel disposed within the susceptor plate at a second injection angle, the second injection channel extending from the second gas channel to a second gas outlet disposed in a second inner edge of a second side member; wherein the second gas outlet injects a third flow of the gas into the reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

A more complete understanding of exemplary embodiments of the present disclosure can be derived by referring to the detailed description and claims when considered in connection with the following illustrative figures.

FIG. 1 illustrates an isometric view of a section of an exemplary reactor system comprising a susceptor ring assembly having a susceptor ring in accordance with one or more embodiments of the disclosure.

FIG. 2 illustrates a plan view of a susceptor ring assembly including a susceptor ring in accordance with one or more embodiments of the disclosure.

FIG. 3 illustrates a cross-sectional view of a susceptor ring in accordance with one or more embodiments of the disclosure.

FIG. 4 illustrates an expanded cross-sectional view of a portion of a susceptor ring in accordance with one or more embodiments of the disclosure.

FIG. 5 illustrates an expanded cross-sectional view of a portion of a susceptor ring in accordance with one or more embodiments of the disclosure.

FIG. 6 illustrates a plan view of a reactor system including a reaction chamber with a susceptor ring disposed within in accordance with one or more embodiments of the disclosure.

FIG. 7 illustrates an exemplary method for injecting a gas into a reaction chamber in accordance with one or more embodiments of the disclosure.

### DETAILED DESCRIPTION

The description of exemplary embodiments of systems and methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “film” and/or “layer” can be used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gases, nitrogen, and the like. In some cases, the term “precursor” can refer to a compound that participates in the chemical reaction that produces another compound, and particularly to a compound that constitutes a film matrix or a main skeleton of a film. In addition, the term “reactant” can be used interchangeably with the term “precursor”.

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

A number of example materials are given throughout the embodiments of the current disclosure; it should be noted that the chemical formulas given for each of the example materials should not be construed as limiting and that the non-limiting example materials given should not be limited by a given example stoichiometry.

As used herein, a “structure” can be or can include a substrate as described herein. Structures can include one or more layers overlying the substrate, such as one or more layers formed according to a method as described herein.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

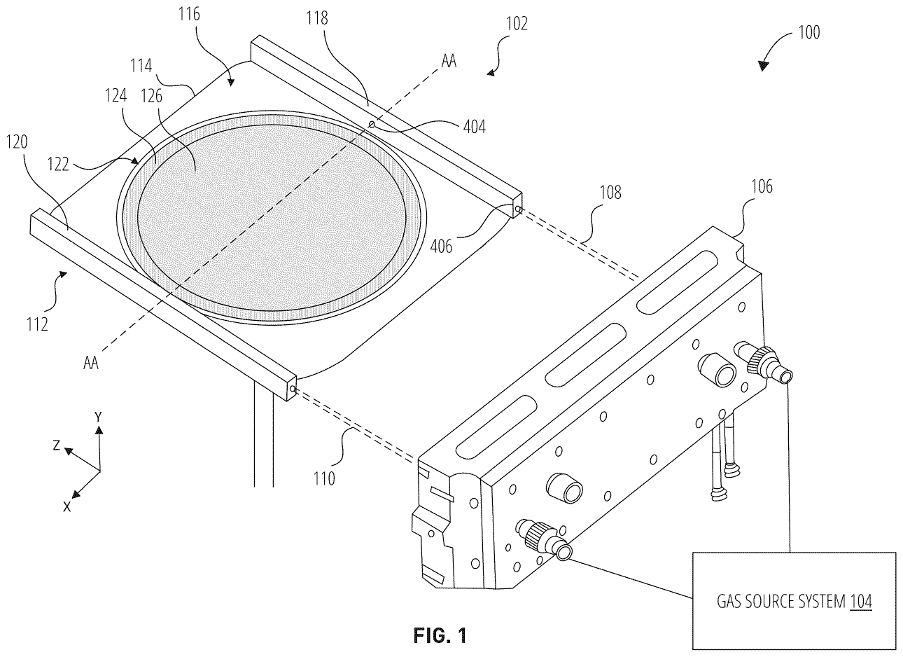

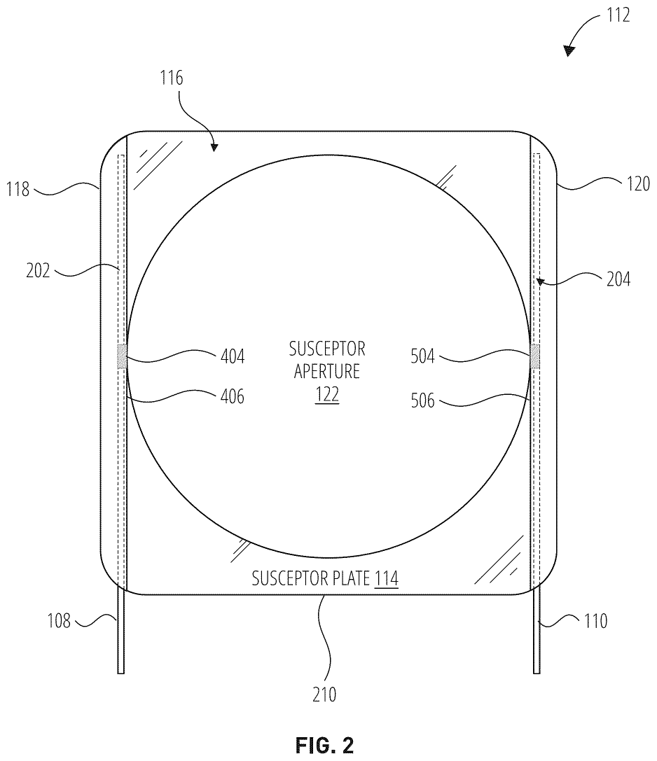

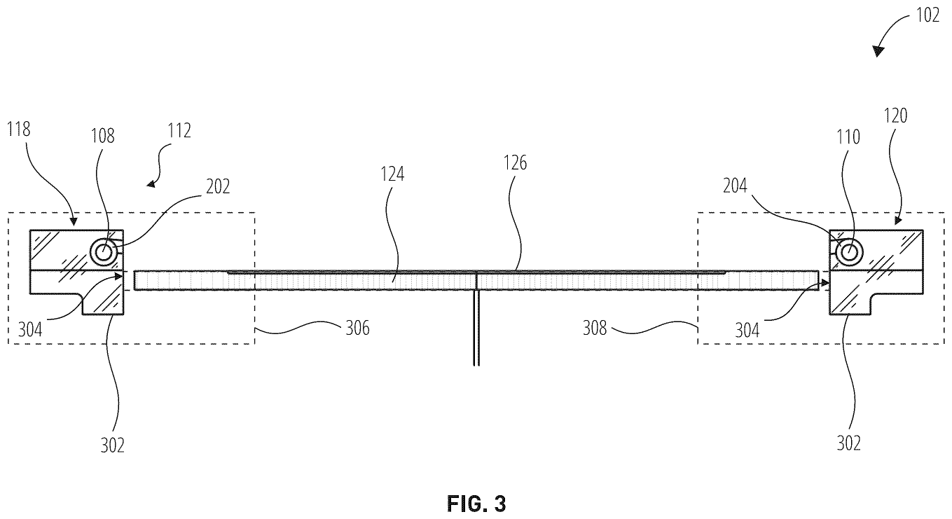

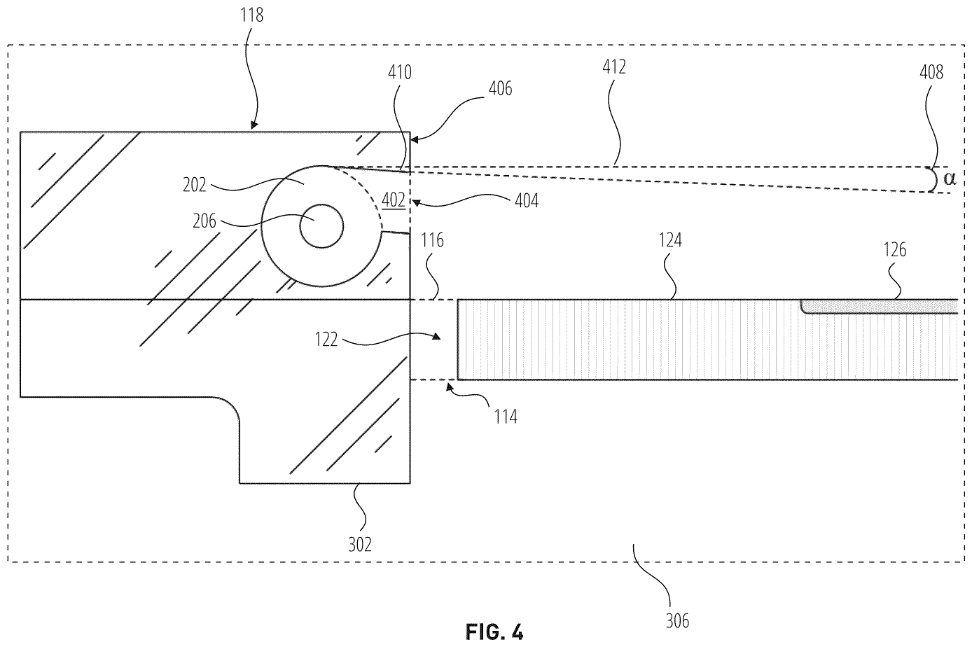

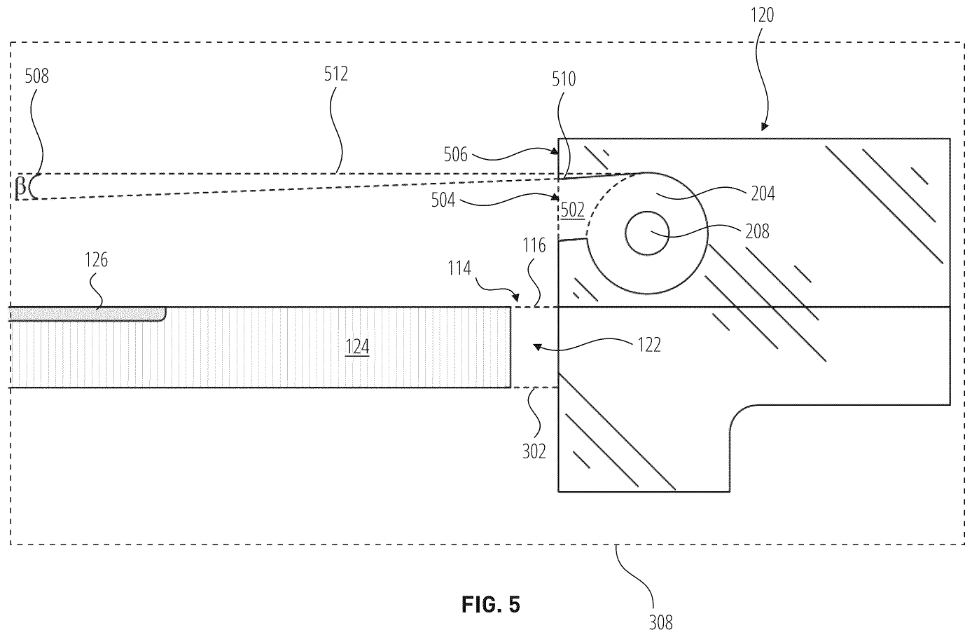

Turning now to the figures, FIGS. 1-5 illustrate various views of susceptor rings and susceptor ring assemblies of the present disclosure. For example, FIG. 1 illustrates an isometric view of a section of an exemplary reactor system comprising a susceptor ring assembly including a susceptor ring with a susceptor in position and a substrate disposed on the susceptor, FIG. 2 illustrates a plan view of the susceptor ring with the susceptor and substrate removed, FIG. 3 illustrates a cross-sectional view of the susceptor ring (through the AA plane illustrated in FIG. 1), and both FIG. 4 and FIG. 5 illustrate expanded cross-sectional views of a portion of a susceptor ring.

In various embodiments and with reference to FIG. 1, an exemplary reactor system 100 comprises a susceptor ring assembly 102 fluidly coupled to a gas source system 104 by means of a flange assembly 106 and one or more injector tube(s), such as, first injector tube 108 and/or second injector tube 110, for example. The injector tubes 108 and 110 are illustrated as dashed lines in FIG. 1 to delineate the susceptor ring assembly 102 from the other features of the reactor system 100. The susceptor ring assembly 102 comprises a susceptor ring 112, as illustrated in isolation in FIG. 2. The susceptor ring 112 can be formed of, for example, graphite or pyrolytic carbon. In certain examples, the susceptor ring 112 is fabricated from bulk graphite or pyrolytic carbon. In such examples the bulk material can be coated (or encapsulated) with silicon carbide (SiC). In certain examples, the susceptor ring 112 comprises a single monolithic body.

With reference to FIG. 2 and FIG. 3, the susceptor ring 112 comprises a susceptor plate 114 having an upper surface 116 and a lower surface 302 (see FIG. 3). The susceptor plate 114 comprises a first side member 118 extending from the upper surface 116 of the susceptor plate 114. In certain embodiments, the susceptor plate 114 comprises a second side member 120 extending from the upper surface 116 of the susceptor plate 114. The second side member 120 can be laterally spaced apart (e.g., along the X-axis as illustrated in FIG. 1) from the first side member 118. In addition, the susceptor plate 114 comprises a susceptor aperture 122 which extends from the upper surface 116 to the lower surface 302 of the susceptor plate. For example, the susceptor ring 112 can include an interior wall 304 (FIG. 3), extending along the circumference of the susceptor aperture 122 from the upper surface 116 to the lower surface 302. The susceptor aperture 122 disposed in the susceptor plate 114 and is constructed and arranged to receive a susceptor 124. The susceptor 124 is configured to receive and retain a substrate 126. A far edge of the substrate 126 can be defined as the outermost 10% of the radius of the substrate. For example, if the radius of substrate 126 is 150 millimeters, then the far edge of substrate 126 can be defined as the area within the last (i.e., outermost) 15 millimeters of a radius of the substrate. In some cases, the far edge can be defined as an area between the outer about 5% and about 15% of the radius of the substrate 126. Film thickness variation, known as roll-up or roll-down, can occur at the far edge of the substrate 126 due to temperature differential during deposition between the center and the edge of the substrate during deposition on an upper surface of substrate 126.

In various embodiments, the susceptor ring 112 comprises a first gas channel disposed within the first side member. For example, FIG. 2 illustrates a plan view of the susceptor ring 112 and comprises an exemplary first gas channel 202 disposed within the first side member 118, the first gas channel 202 being illustrated as a dashed line to denote the gas channel is disposed within the interior of the first side member 118. The first gas channel 202 is configured to couple with the first injector tube 108. In some embodiments, the susceptor ring 112 comprises a second gas channel disposed within the second side member. For example, FIG. 2 illustrates an exemplary second gas channel 204 disposed within the second side member 120, the second gas channel 204 again being illustrated as a dashed line to denote the second gas channel is disposed within the interior of the second side member 120. The second gas channel 204 is configured to couple with the second injector tube 110.

FIG. 3 illustrates a cross-sectional view of the susceptor ring 112, through the AA plane illustrated in FIG. 1. As illustrated in FIG. 3, the first injector tube 108 can be fluidly coupled with the first gas channel 202 disposed within the first side member 118. In one aspect, the first injector tube 108 is at least partially disposed within the first gas channel 202. Likewise, in some embodiments, the second injector tube 110 is fluidly coupled with the second gas channel 204 disposed within the second side member 120. In one aspect, the second injector tube 110 is at least partially disposed within the second gas channel 204. Gas supplied from the gas source system 104 (FIG. 1), can be transported through the injector tubes (206, 208) into the first gas channel 202 and optionally the second gas channel 204 and therethrough to the substrate, as described in detail below.

In some embodiments, the first gas channel 202 (and the second gas channel 204 if present) can extend a first edge 210 to a distance from the first edge 210. For example, first gas channel 202 (and second if present) can extend from 30 millimeters to 250 millimeters from first edge 210.

The dashed regions (306 and 308) of the susceptor ring assembly 102 of FIG. 3 are expanded and illustrated in further detail in FIG. 4 and FIG. 5, respectively. For example, FIG. 4 illustrates the first side member 118, extending upward (i.e., along the Y-axis illustrated in FIG. 1) from the upper surface 116 of the susceptor plate 114, the susceptor aperture 122, as well a portion of the susceptor 124 with a substrate 126 disposed thereon. The first gas channel 202 is disposed in the first side member 118 and is coupled to the first injector tube 206, as previously described.

In various embodiments, a first injection channel is disposed within the first side member 118. With reference to FIG. 4, a first injection channel 402 extends from the first gas channel 202 to a first gas outlet 404 disposed in a first inner edge 406 of the first side member 118. The first gas outlet 404 is further illustrated in FIG. 1 and FIG. 2. In such embodiments, the first gas outlet 404 is in fluid communication with the first gas channel 202, which is in turn fluidly coupled to the first injector tube 206. As such, a gas supplied from the gas source system 104 (FIG. 1) to first injector tube 206 can flow to the first gas channel 202 disposed within the susceptor plate 114, and then from the first gas channel 202 into the first injection channel 402, and subsequently through the first injection channel 402 to the first gas outlet 404, ultimately reaching the substrate 126 supported by the susceptor 124.

In various embodiments, the first injection channel 402 is constructed and arranged at a first injection angle 408 (as denoted by α in FIG. 4). The first injection angle 408 can be defined as the angle between an upper wall 410 of the first injection channel 402 and a plane parallel to the upper surface 116 of the susceptor plate 114, illustrated by plane 412. In some embodiments, the first injection angle 408 (α) is between 5 degrees and 35 degrees, between 10 degrees and 30 degrees, or between 15 degrees and 25 degrees. In some embodiments, the first injection angle 408 (α) is less than 35 degrees, less than 30 degrees, less than 25 degrees, less than 20 degrees, less than 15 degrees, less than 10 degrees, or less than 5 degrees.

As a further example, FIG. 5 illustrates the second side member 120, extending upward (i.e., along the Y-axis illustrated in FIG. 1) from the upper surface 116 of the susceptor plate 114, the susceptor aperture 122, as well a portion of the susceptor 124 with a substrate 126 disposed thereon. The second gas channel 204 is disposed in the second side member 120 and is coupled to the second injector tube 208, as previously described.

In various embodiments, a second injection channel is disposed within the second side member 120. With reference to FIG. 5, a second injection channel 502 extends from the second gas channel 204 to a second gas outlet 504 disposed in a second inner edge 506 of the second side member 120. The second gas outlet 504 is further illustrated in FIG. 2. In such embodiments, the second gas outlet 504 is in fluid communication with the second gas channel 204, which is in turn fluidly coupled to the second injector tube 208. As such, a gas supplied from the gas source system 104 (FIG. 1) to second injector tube 208 can flow to the second gas channel 204 disposed within the susceptor plate 114, and then from the second gas channel 204 into the second injection channel 502, and subsequently through the second injection channel 502 to the second gas outlet 504, ultimately reaching the substrate 126 supported by the susceptor 124.

In various embodiments, the second injection channel 502 is constructed and arranged at a second injection angle 508 (as denoted by β in FIG. 5). The second injection angle 508 can be defined as the angle between an upper wall 510 of the second injection channel 502 and a plane parallel to the upper surface 116 of the susceptor plate 114, illustrated by plane 512. In some embodiments, the second injection angle 508 (β) is between 5 degrees and 35 degrees, between 10 degrees and 30 degrees, or between 15 degrees and 25 degrees. In some embodiments, the second injection angle 508 (β) is less than 35 degrees, less than 30 degrees, less than 25 degrees, less than 20 degrees, less than 15 degrees, less than 10 degrees, or less than 5 degrees.

In various embodiments and with reference to FIG. 2, the first gas outlet 404 and the second gas outlet 504 are positioned laterally opposing each other on either side of the susceptor aperture 122.

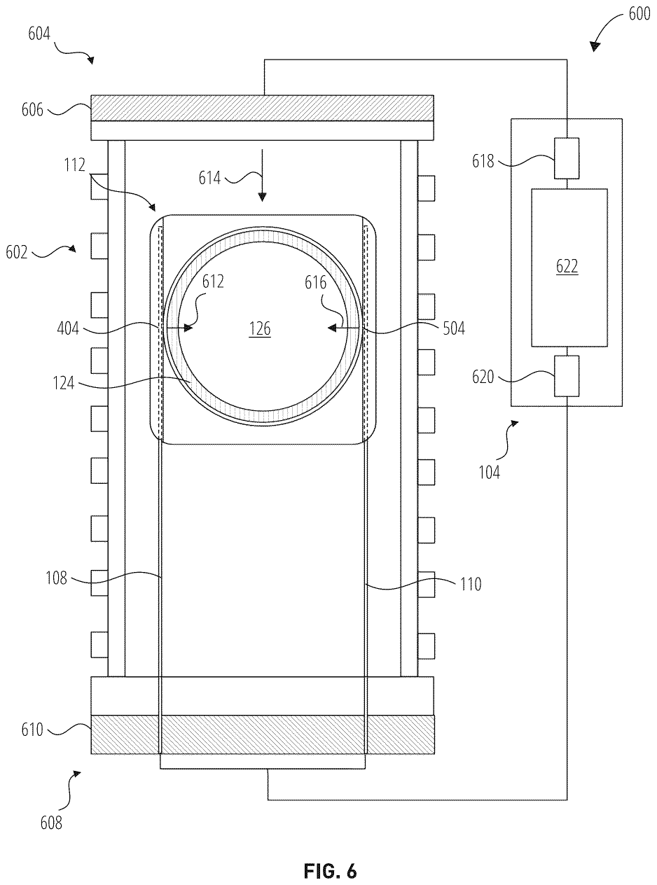

With reference to FIG. 6, a plan view of an exemplary reactor system 600 according to an embodiment of the present disclosure is illustrated. The reactor system 600 can comprise a reaction chamber 602 with an injection end 604 of the reaction chamber 602 comprising an injection flange 606, and an exhaust end 608 of the reaction chamber 602 comprising an exhaust flange 610. The reactor system 600 comprises the susceptor ring 112 as described above.

A substrate 126 can be provided in the reaction chamber 602 on the susceptor 124. In various embodiments, the substrate 126 can be lifted above the susceptor and lowered on to the susceptor 124 for processing with one or more lift pins (not illustrated). In various embodiments, an exhaust system (not illustrated) is fluidly coupled to the exhaust flange 610 to remove process gases and precursors from the reaction chamber.

In various embodiments, the first gas outlet 404 of the susceptor ring 112 is configured to independently provide a first flow of a gas into the reaction chamber 602 (as indicated by first gas flow 612) and the injection flange 606 is configured to independently provide a second flow of the gas into the reaction chamber 602 (as indicated by second gas flow 614). In certain examples, the second gas outlet 504 of the susceptor ring 112 is configured to provide a third flow of the gas into the reaction chamber 602 (as indicated by third gas flow 616). In some embodiments, the first flow of the gas (612) is substantially perpendicular to the second flow of the gas (614).

Reactor system 600 can include a gas source system 104 fluidly coupled to the first injector tube 108 (and optionally the second injector tube 110). In addition, the gas source system 104 can be fluidly coupled to the injection flange 606. In some embodiments, the gas source system 104 comprises a first flow controller 618 configured for controlling the first flow (612) into the reaction chamber and a second flow controller 620 is configured for controlling the second flow (614) into the reaction chamber. The gas source system 104 can include one or more gas sources, such as, for example, precursors source, dopant sources, etchant sources, and the like. In certain embodiments, the gas source system 104 comprises a dopant gas source 622 and the gas supplied to the first injector tube 108 and the injection flange 606 is a dopant gas. In such examples, the dopant gas can comprise at least one of a phosphorus dopant, a boron dopant, and an arsenic dopant.

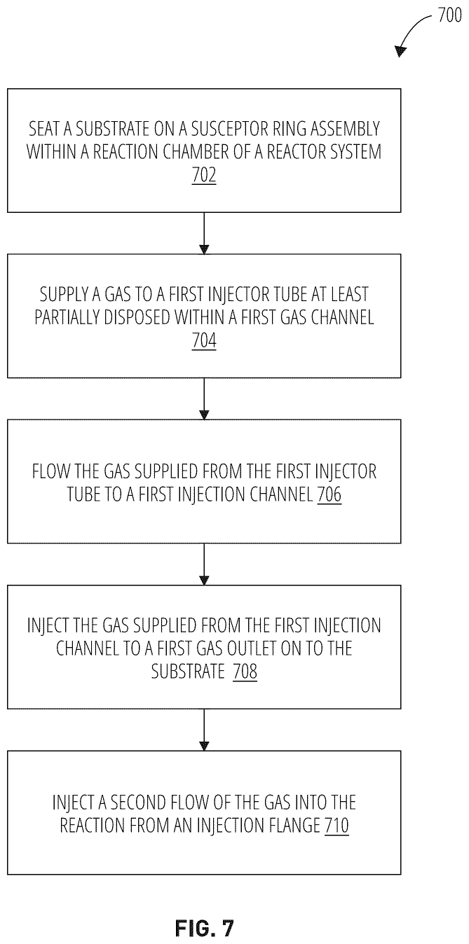

In accordance with embodiments of the disclosure, a method for injecting a gas into a reaction chamber is provided. With reference to FIG. 7, an exemplary method 700 according to embodiments of the present disclosure is illustrated.

In various embodiments, method 700 comprising, seating a substrate on a susceptor ring assembly within a reaction chamber of a reactor system, the susceptor ring assembly comprising a monolithic susceptor ring including a susceptor plate having an upper surface and a lower surface, a first side member extending from the upper surface, and a susceptor aperture extending from the upper surface to the lower surface; a first gas channel disposed within the first side member, and a first injection channel disposed within the first side member at a first injection angle, the first injection channel extending from the first gas channel to a first gas outlet disposed in a first inner edge (step 702).

In various embodiments, method 700 comprises supplying a gas to the first injector tube at least partially disposed within the first gas channel (step 704).

In various embodiments, method 700 comprises flowing the gas supplied from the first injector tube to the first injection channel (step 706).

In various embodiments, method 700 comprises injecting a first flow of the gas supplied from the first injection channel from the first gas outlet on to the substrate seated on the rotatable susceptor of the susceptor ring assembly (step 708).

In various embodiments, method 700 comprises injecting a second flow of the gas from an injection flange coupled to the reaction chamber (step 710). In such embodiments, the first flow of the gas can be substantially perpendicular to the second flow of the gas. In such embodiments, the first flow of the gas can be independently controlled by a first flow controller and the second flow of the gas can be independently controlled by a second flow controller. The first flow of gas and the second flow of gas can be the same gas or a different gas. For example, the first flow can include a mixture of gases, such as a silicon-containing precursor, a germanium-containing precursor, a dopant-containing precursor, and/or an etchant as described above. In certain examples, the gas comprises a dopant gas, such as, for example, a phosphorus dopant, a boron dopant, or an arsenic dopant.

The example embodiments of the disclosure described above do not limit the scope of the invention, since these embodiments are merely examples of the embodiments of the invention, which are defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A susceptor ring for use in a reactor system, the susceptor ring comprising:
a susceptor plate having an upper surface and a lower surface, a first side member extending from the upper surface, and a susceptor aperture extending from the upper surface to the lower surface and configured to receive a susceptor configured to support a substrate;
a first gas channel disposed within the first side member, the first gas channel configured to couple with a first injector tube for supplying a gas to the first gas channel; and
a first injection channel disposed within the first side member at a first injection angle, the first injection channel extending from the first gas channel to a first gas outlet disposed in a first inner edge of the first side member.

2. The susceptor ring of claim 1, wherein the susceptor plate comprises a single monolithic body.

3. The susceptor ring of claim 2, wherein the first injection angle is between 5 degrees and 35 degrees.

4. The susceptor ring of claim 3, wherein the susceptor plate further comprises a second side member longitudinally spaced apart from the first side member and extending from the upper surface of the susceptor plate.

5. The susceptor ring of claim 4, further comprising a second gas channel disposed within the susceptor plate, the second gas channel configured to couple with a second injector tube for supplying the gas to the second gas channel, and a second injection channel disposed within the susceptor plate at a second injection angle, the second injection channel extending from the second gas channel to a second gas outlet disposed in a second inner edge of the second side member.

6. The susceptor ring of claim 5, wherein the second injection angle is between 5 degrees and 35 degrees.

7. The susceptor ring of claim 6, wherein the first gas outlet and the second gas outlet are positioned laterally opposing each other on either side of the susceptor aperture.

8. A reactor system comprising:
a reaction chamber comprising an injection end coupled to an injection flange and an exhaust end coupled to an exhaust flange;
a susceptor ring assembly disposed within the reaction chamber, the susceptor ring assembly comprising:
a monolithic susceptor ring comprising a susceptor plate having an upper surface and a lower surface, a first side member extending from the upper surface, a susceptor aperture extending from the upper surface to the lower surface, a first gas channel disposed within the first side member, and a first injection channel disposed within the first side member at a first injection angle, the first injection channel extending from the first gas channel to a first gas outlet disposed in a first inner edge;
a first injector tube coupled to the first gas channel and at least partially disposed within the first gas channel; and
a susceptor at least partially disposed within the susceptor aperture and configured to support a substrate,
wherein the first gas outlet is configured to independently provide a first flow of a gas into the reaction chamber and the injection flange is configured to independently provide a second flow of the gas into the reaction chamber and the first flow is substantially perpendicular to the second flow.

9. The reactor system of claim 8, further comprising a gas source system fluidly coupled to the first injector tube and the injection flange, the gas source system including a first flow controller for controlling the first flow and a second flow controller for controlling the second flow.

10. The reactor system of claim 9, wherein the gas source system comprises a dopant gas source and the gas supplied to the first injector tube and the injection flange is a dopant gas.

11. The reactor system of claim 8, wherein the first injection angle is between 5 degrees and 35 degrees.

12. The reactor system of claim 11, wherein the susceptor plate further comprises a second side member longitudinally spaced apart from the first side member and extending from the upper surface, a second gas channel disposed within the susceptor plate, and a second injection channel disposed within the susceptor plate at a second injection angle, the second injection channel extending from the second gas channel to a second gas outlet disposed in a second inner edge of the second side member.

13. The reactor system of claim 12, further comprising a second injector tube coupled to the second gas channel and at least partially disposed within the second gas channel.

14. The reactor system of claim 13, wherein the first gas outlet and the second gas outlet are positioned laterally opposing each other on either side of the susceptor aperture.

15. A method of injecting a gas into a reaction chamber, the method comprising:
seating a substrate on a susceptor ring assembly within a reaction chamber of a reactor system, the susceptor ring assembly comprising:
a monolithic susceptor ring comprising a susceptor plate having an upper surface and a lower surface, a first side member extending from the upper surface, and a susceptor aperture extending from the upper surface to the lower surface; a first gas channel disposed within the first side member; and a first injection channel disposed within the first side member at a first injection angle, the first injection channel extending from the first gas channel to a first gas outlet disposed in a first inner edge;
a first injector tube coupled to the first gas channel and at least partially disposed within the first gas channel;
a rotatable susceptor at least partially disposed within the susceptor aperture;
supplying the gas to the first injector tube at least partially disposed within the first gas channel;
flowing the gas supplied from the first injector tube to the first injection channel;
injecting a first flow of the gas supplied from the first injection channel from the first gas outlet on to the substrate seated on the rotatable susceptor of the susceptor ring assembly; and
injecting a second flow of the gas from an injection flange coupled to the reaction chamber.

16. The method of claim 15, wherein the first flow of the gas is substantially perpendicular to the second flow of the gas.

17. The method of claim 16, wherein the first flow of the gas is independently controlled by a first flow controller and the second flow of the gas is independently controlled by a second flow controller.

18. The method of claim 17, wherein the gas comprises a dopant gas.

19. The method of claim 18, wherein the first injection angle is between 5 degrees and 35 degrees, and the dopant gas is injected through the first gas outlet downward toward and across the substrate.

20. The method of claim 19, wherein the monolithic susceptor ring further comprises a second gas channel disposed within the susceptor plate, the second gas channel configured to couple with a second injector tube for supplying the gas to the second gas channel; and a second injection channel disposed within the susceptor plate at a second injection angle, the second injection channel extending from the second gas channel to a second gas outlet disposed in a second inner edge of a second side member, wherein the second gas outlet injects a third flow of the gas into the reaction chamber.
